(19) United States
(12) Patent Application Publication
(10) Pub. No.: US 2025/0348219 A1
(43) Pub. Date: Nov. 13, 2025

(54) METHODS AND APPARATUSES FOR OPERATING A MEMORY DEVICE

(71) Applicant: Yangtze Memory Technologies Co., Ltd., Wuhan (CN)

(72) Inventors: Weijun WAN, Wuhan (CN); Zhuo CHEN, Wuhan (CN)

(21) Appl. No.: 18/777,970

(22) Filed: Jul. 19, 2024

(30) Foreign Application Priority Data
May 10, 2024 (CN) 202410578455.5

(51) Int. Cl. G06F 3/06

(52) U.S. Cl. CPC G06F 3/0613; G06F 3/0659; G06F 3/0679

(57) ABSTRACT

The present disclosure relates to methods and devices for operating a memory device. In one example, a memory device includes a memory array that includes memory cells, and a peripheral circuit coupled to the memory array. The peripheral circuit includes a micro controller unit (MCU) and a plurality of circuits controlled by the MCU. The MCU is configured to switch between a first register and a second register that are coupled to a first circuit of the plurality of circuits.

### CROSS-REFERENCE TO RELATED APPLICATIONS

This application claims priority to Chinese Patent Application No. 202410578455.5, filed on May 10, 2024, which is hereby incorporated by reference in its entirety.

### TECHNICAL FIELD

This present disclosure generally relates to the field of semiconductor technology, and more particularly, to systems and methods for operating a memory device.

### BACKGROUND

Flash memory is a low-cost, high-density, nonvolatile solid-state storage medium that can be electrically erased and reprogrammed. Flash memory includes NOR flash memory and NAND flash memory. The growing demands of consumer electronics, cloud computing, and big data bring a constant need of flash memories of larger capacity and better performance. Nowadays, flash memory devices are designed with stringent performance and reliability requirements.

### SUMMARY

The present disclosure relates to methods and devices for operating a memory device. In an example, a memory device includes a memory array that includes memory cells, and a peripheral circuit coupled to the memory array. The peripheral circuit includes a micro controller unit (MCU) and a plurality of circuits controlled by the MCU. The MCU is configured to switch between a first register and a second register that are coupled to a first circuit of the plurality of circuits.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic diagram of a memory device including a peripheral circuit, according to some aspects of the present disclosure.

FIG. 2 illustrates some example circuits of a peripheral circuit, according to some aspects of the present disclosure.

FIG. 3 illustrates an example of a schematic diagram of a peripheral circuit, according to some aspects of the present disclosure.

FIG. 4A illustrates an example of a schematic diagram of connections between two registers of a circuit, according to some aspects of the present disclosure.

FIG. 4B illustrates another example of a schematic diagram of connections between two registers of a circuit, according to some aspects of the present disclosure.

FIG. 5 illustrates an example method of operating a memory device, according to some aspects of the present disclosure.

FIG. 6A illustrates another example method of operating a memory device, according to some aspects of the present disclosure.

FIG. 6B illustrates another example method of operating a memory device, according to some aspects of the present disclosure.

FIG. 7 illustrates a block diagram of an example system having a memory device, according to some aspects of the present disclosure.

FIG. 8A illustrates a diagram of a memory card having a memory device, according to some aspects of the present disclosure.

FIG. 8B illustrates a diagram of a solid-state drive (SSD) having a memory device, according to some aspects of the present disclosure.

Like reference numbers and designations in the various drawings indicate like elements.

### DETAILED DESCRIPTION

A flash memory device, such as a NAND memory device, can include a memory array and a peripheral circuit that perform operations on the memory array. The peripheral circuit can include a control logic and a plurality of circuits controlled by the control logic. Current designs of the control logic can include a state machine (STM) architecture and a microcontroller unit (MCU) architecture. Under the STM architecture, each circuit is controlled by a corresponding microprocessor. The microprocessors can run operations of one cycle in parallel. In contrast, under the MCU architecture, a general-purpose MCU can control multiple circuits through a bus. Due to factors such as the data width of the bus, the MCU performs operations of one cycle in serial. In some cases, the MCU architecture can allow the implementation of complex control algorithms and greater flexibility in modifying control algorithms without the need for re-fabrication. For example, by introducing the PC Re-Map structure, problematic or improvable firmware blocks can be mapped to new firmware blocks, which can make post-silicon modifications more convenient and improves design and verification efficiency.

The present disclosure provides techniques to operate a memory device with control logic under the MCU architecture. In some implementations, a circuit of the peripheral circuit can have a prime register and a backup register that couple the circuit to the MCU. The prime register and the backup register can share the same address. The MCU can switch between the prime register and the backup register. For example, when the circuit is performing an operation indicated by configuration parameters stored in the prime register, the MCU can send configuration parameters to the backup register for a subsequent operation.

The techniques described in the present disclosure can be implemented to achieve one or more of the following advantages. For example, because the MCU does not need to hold off sending configuration parameters for subsequent operations until the circuit completes the current operation, the operational efficiency of the MCU can be enhanced. Moreover, read time and program time of the memory device can be reduced to improve the performance of the memory device.

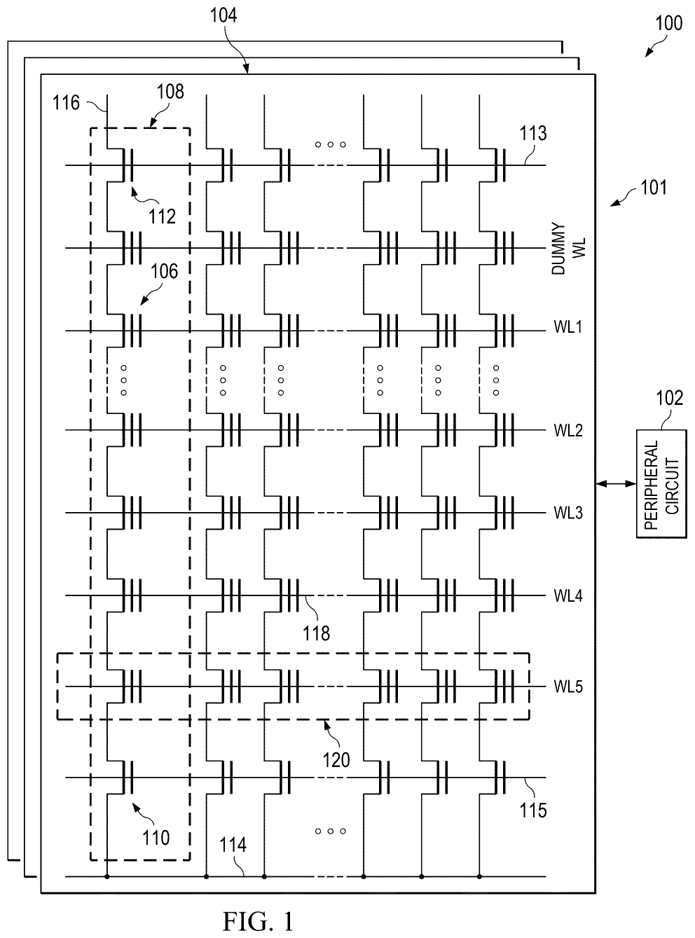

FIG. 1 illustrates an example of a schematic circuit diagram of a memory device 100 including a peripheral circuit 102, according to some aspects of the present disclosure. The memory device 100 can include a memory cell array 101 and a peripheral circuit 102 coupled to the memory cell array 101. The memory cell array 101 can be a NAND Flash memory cell array in which memory cells 106 are provided in the form of an array of NAND memory strings 108 each extending vertically above a substrate (not shown in FIG. 1). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a storage layer of the memory cell 106. The logic state (e.g., data) of each memory cell 106 in the block 104 can be determined based on the threshold voltage Vth of the memory cell 106. Each memory cell 106 can be a floating gate type memory cell including a floating-gate transistor, or a charge trap type memory cell including a charge-trap transistor.

In some implementations, each memory cell 106 is a single-level cell (SLC) with two possible memory states that can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 1, each NAND memory string 108 can include a source select gate (SSG) 110 at its source end and a drain select gate (DSG) 112 at its drain end. The SSG 110 and the DSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, NAND memory strings 108 in the same block 104 have an array common source (ACS), according to some implementations. The DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage (e.g., above the threshold voltage of the transistor having the DSG 112) or a deselect voltage (e.g., 0 V) to the respective DSG 112 through one or more DSG lines 113, and/or by applying a select voltage (e.g., above the threshold voltage of the transistor having the SSG 110) or a deselect voltage (e.g., 0 V) to the respective SSG 110 through one or more SSG lines 115.

As shown in FIG. 1, NAND memory strings 108 can be organized into multiple blocks 104, each of which can have a common source line 114 coupled to the ACS. In some implementations, each block 104 can serve as a basic data unit for erase operations, such that memory cells 106 on the same block 104 are erased at the same time. To erase memory cells 106 in a selected block 104, the source lines 114 coupled to the selected block 104 and unselected blocks in the same plane can be biased with an erase voltage (Vers). For example, the erase voltage can be a high positive voltage (e.g., 20 V or more). In some implementations, an erase operation can be performed at a half-block level, a quarter-block level, or a level having any suitable number of blocks or fractions of a block.

The memory cells 106 of adjacent NAND memory strings 108 can be coupled through word lines 118. The word line 118 can select which row of memory cells 106 is affected by read and program operations. In some implementations, the memory cell 106 is a SLC, and each word line 118 is coupled to a page 120 of memory cells 106, which is the basic data unit for program operations. If the memory cell 106 is an MLC that stores two bits of data per cell, each word line 118 can correspond to two pages. If memory cell 106 is a TLC, each word line 118 can correspond to three pages. If memory cell 106 is a QLC, each word line 118 can correspond to four pages. The size of a page 120 in bits is associated with the number of NAND memory strings 108 coupled by word line 118 in a block 104. Each word line 118 can include a gate line coupled to a plurality of control gates (gate electrodes) of a plurality of memory cells 106 in the respective page 120. Example word lines shown in FIG. 1 include dummy WL, WL1, WL2, WL3, WL4, and WL5 that are between one or more DSG lines 113 and one or more SSG lines 115.

The peripheral circuit 102 can be coupled to the memory cell array 101 through bit lines 116, word lines 118, source lines 114, SSG lines 115, and DSG lines 113. The peripheral circuit 102 can include any suitable analog, digital, and mixed-signal circuits for facilitating the operations of the memory cell array 101 by applying and sensing voltage signals and/or current signals to and from each target memory cell 106 through bit lines 116, word lines 118, source lines 114, SSG lines 115, and DSG lines 113.

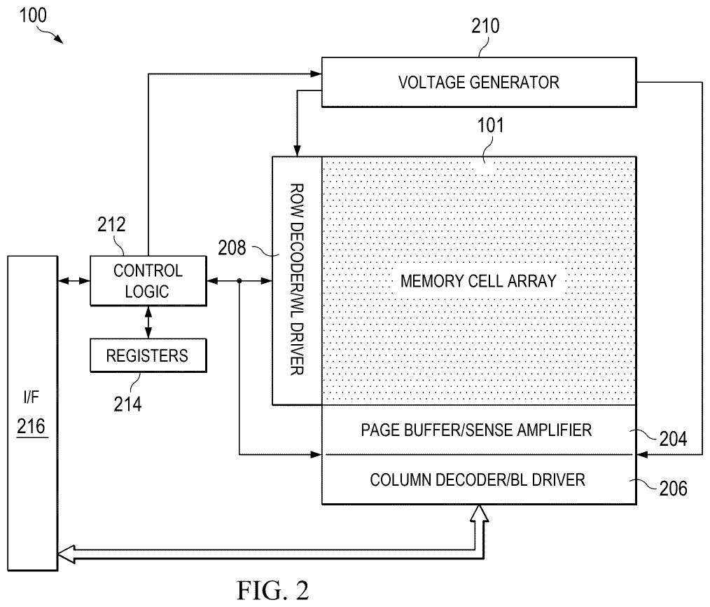

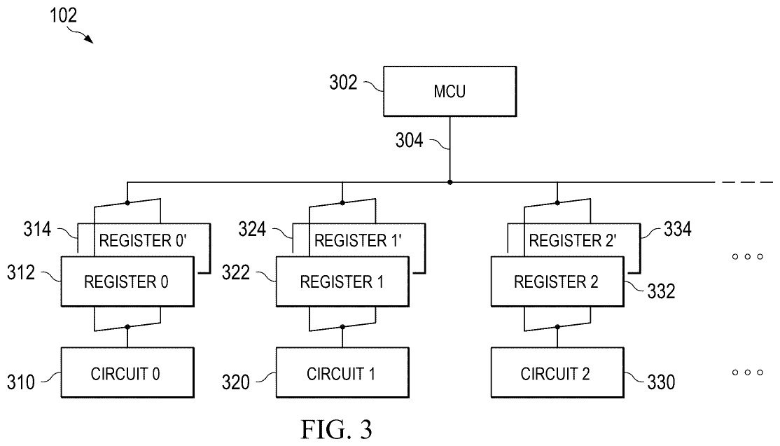

FIG. 2 illustrates some example circuits of a peripheral circuit (e.g., the peripheral circuit 102 of FIG. 1), according to some aspects of the present disclosure. The peripheral circuit can include control logic 212, registers 214 coupled to the control logic 212, an interface 216, and other circuits controlled by the control logic 212, including a page buffer/sense amplifier 204, a column decoder/bit line driver 206, a row decoder/word line driver 208, and a voltage generator 210. A data bus of the control logic can connect the control logic 212 with the other circuits and transmit signals and data from and to the control logic 212. In some examples, additional circuits not shown in FIG. 3 may be included as well.

The page buffer/sense amplifier 204 can be configured to read and program (write) data from and to memory cell array 101 according to the control signals from the control logic 212. In an example, the page buffer/sense amplifier 204 may store one page of program data (write data) to be programmed into one page 120 of the memory cell array 101. In another example, the page buffer/sense amplifier 204 may perform program verify operations to ensure that the data has been properly programmed into memory cells 106 coupled to selected word lines 118. In still another example, the page buffer/sense amplifier 204 may also sense the low power signals from the bit line 116 that represents a data bit stored in memory cell 106, and amplify the small voltage swing to recognizable logic levels in a read operation. The column decoder/bit line driver 206 can be configured to be controlled by the control logic 212 and select one or more NAND memory strings 108 by applying bit line voltages generated from the voltage generator 210.

The row decoder/word line driver 208 can be configured to be controlled by the control logic 212 and select/deselect blocks 104 of the memory cell array 101 and select/deselect word lines 118 of the block 104. The row decoder/word line driver 208 can be further configured to drive word lines 118 using word line voltages generated from the voltage generator 210. In some implementations, the row decoder/word line driver 208 can also select/deselect and drive SSG lines 115 and DSG lines 113. As described below in detail, the row decoder/word line driver 208 is configured to apply a program voltage to selected word line 118 in a program operation on memory cell 106 coupled to selected word line 118.

The voltage generator 210 can be configured to be controlled by the control logic 212 and generate the word line voltages (e.g., read voltage, program voltage, pass voltage, local voltage, verify voltage, etc.), bit line voltages, and source line voltages to be supplied to the memory cell array 101.

The control logic 212 can be coupled to each circuit described above and configured to control operations of each circuit. The control logic 212 can be implemented by microprocessors, microcontrollers (also known as Micro Controller Units, MCU), Digital Signal Processors (DSP), Application Specific Integrated Circuits (ASIC), Field Programmable Gate Arrays (FPGA), Programmable Logic Devices (PLD), state machines, gating logic, discrete hardware circuits, and other appropriate hardware, firmware, and/or software configured to perform the various functions described. The registers 214 can be coupled to the control logic 212 and include status registers, command registers, and address registers for storing status information, command operation codes (OP codes), and command addresses for controlling the operations of each circuit.

The interface 216 can be coupled to the control logic 212 and act as a control buffer to buffer and relay control commands received from a host (not shown) to the control logic 212 and status information received from the control logic 212 to the host. The interface 216 can also be coupled to the column decoder/bit line driver 206 via a data bus, and act as a data input/output (I/O) interface and a data buffer to buffer and relay data to and from the memory cell array 101.

FIG. 3 illustrates an example of a schematic diagram of a peripheral circuit 102, according to some aspects of the present disclosure. The peripheral circuit 102 includes control logic (e.g., control logic 212 of FIG. 2) and circuits 310, 320, 330 (e.g., one or more of page buffer/sense amplifier 204, column decoder/bit line driver 206, row decoder/word line driver 208, and voltage generator 210 of FIG. 2) controlled by the control logic. The control logic can be implemented by one or more MCUs 302. In some implementations, the control logic can include multiple types of MCUs 302 to control circuits 310, 320, 330 of different functions. For example, the control logic can include three types of MCUs: main program microcontroller (MP_MCU), core microcontroller (CORE_MCU), and page buffer microcontroller (PB_MCU). The MP_MCU can be configured to run the main program and control the CORE_MCU and the PB_MCU. The CORE MCU can be configured to control operations of circuits such as row decoders (e.g., row decoder/word line driver 208 in FIG. 2), column decoders (e.g., column decoder/bit line driver 206 in FIG. 2), and other analog circuits. The PB_MCU can be configured to control operations of page buffers (e.g., page buffer/sense amplifier 204 in FIG. 2).

The MCU 302 can communicate with a register of one of the circuits 310, 320, 330 through a bus 304. In some implementations, the bus 304 can include a data bus, an address bus, and a clock control bus. The data bus can have a data width of 8 bits, 16 bits, 32 bits, etc. That is, the data bus can transmit 8 bits, 16 bits, 32 bits, or other number of bits of data at one time. The address bus can transmit address signals that indicate a target register to receive the data transmitted by the data bus. For example, the address bus can transmit the address signal during the data transmission of the data bus. The clock control bus can transmit clock signals that synchronize the timing of different operations of different circuits 310, 320, 330.

In some implementations, each circuit 310 can have one register 312 that receives data from the MCU 302. The data received by the register 312 can include configuration parameters that can configure the circuit 310 for an upcoming operation. For example, circuit 0, circuit 1, circuit 2 are coupled to register 0, register 1, register 2, respectively.

Using circuit 0 as an example, register 0 can first receive from the MCU 302 data that configure circuit 0 to perform a first operation (e.g., configuring word line drivers to select target word lines). Register 0 can hold the data when circuit 0 performs the first operation. After circuit 0 has completed the first operation, register 0 can receive from the MCU 302 data that configure circuit 0 to perform a subsequent operation. Circuit 1, circuit 2, other circuits controlled by MCU 302 can operate in coordination with their respective registers in similar ways.

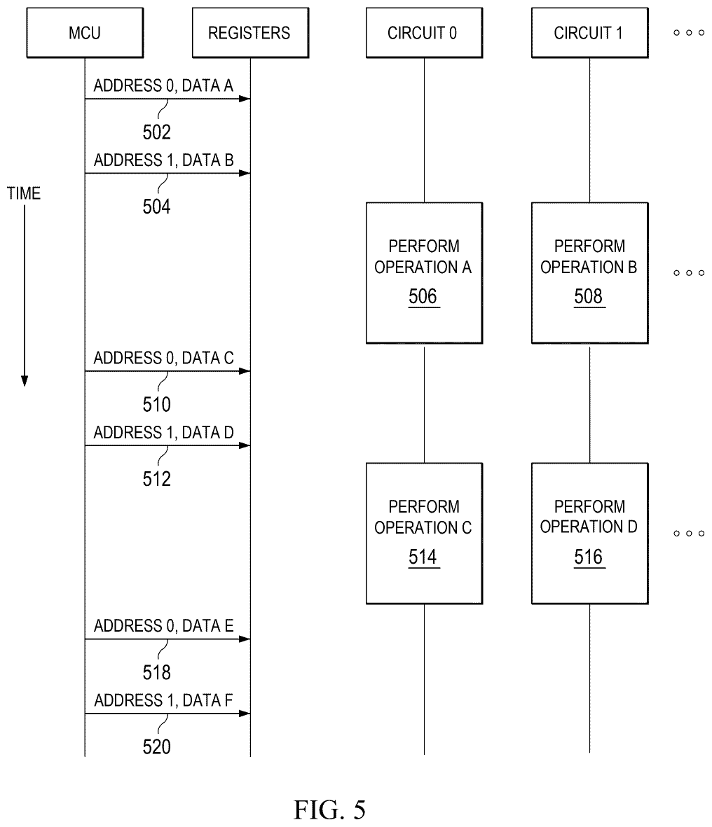

Specifically, with reference to FIG. 5, at 502, the MCU 302 sends data A and address 0 (e.g., address of register 0) through the bus 304. Register 0 receives data A, which can configure circuit 0 to perform operation A. At 504, the MCU 302 sends data B and address 1 (e.g., address of register 1) through the bus 304. Register 1 receives data B, which can configure circuit 1 to perform operation B.

At 506, circuit 0 can perform operation A based on configuration parameters in data A stored in register 0. In the meantime, register 0 can hold data A until operation A is completed. At 508, circuit 1 can perform operation B based on configuration parameters in data B stored in register 1. In the meantime, register 1 can hold data B until operation A is completed. In some implementations, 506 and 508 can start synchronously, according to the clock signal transmitted by the clock control bus.

At 510, after circuit 0 completes operation A, the MCU 302 sends data C and address 0 through the bus 304. Register 0 receives data C, which can configure circuit 0 to perform operation C. At 512, after circuit 1 completes operation B, the MCU sends data D and address 1 through the bus 304. Register 1 receives data D, which can configure circuit 1 to perform operation D. At 514, circuit 0 performs operation C. At 516, circuit 1 performs operation D. In some implementations, 506 and 508 can start synchronously.

At 518, after circuit 0 completes operation C, the MCU 302 sends data E and address 0 through the bus 304. Register 0 receives data E, which can configure circuit 0 to perform operation E. At 520, after circuit 1 completes operation D, the MCU 302 sends data F and address 1 through the bus 304. Register 1 receives data F, which can configure circuit 1 to perform operation F.

It should be noted that FIG. 5 shows two circuits for illustration purposes only. In some implementations, the peripheral circuit 102 can include multiple circuits 310 operating in similar ways. That is, between 502 and 506, the MCU may need to transmit data to registers of circuit 2, 3, . . . , n. Due to a limit of data width of the bus 304, the MCU 302 may need to transmit data to circuits 0-n in sequence, which can take multiple clocks to complete. It can be noted from FIG. 5 that, under the architecture where one circuit is coupled to one register, the bus 304 is idle between 504 and 510 and between 512 and 518. That is, no data or signal is transmitted when the circuits are performing the operations.

Referring back to FIG. 3, in some implementations, each circuit 310 can have two registers 312, 314 that can alternatingly receive data from the MCU 302. One register 312 can be referred to as a prime register. The other register 314 can be referred to as a backup register. For example, circuit 0 can be coupled to register 0 (prime register) and register 0′ (backup register); circuit 1 can be coupled to register 1 (prime register) and register 1′ (backup register); and circuit 2 can be coupled to register 2 (prime register) and register 2′ (backup register). The prime register and the backup register can have the same address and the same configuration. In some implementations, the prime register and the backup register of can be coupled to a multiplexer (MUX), so that the MCU 302 can send an enable signal to the MUX to switch between the prime register and the backup register.

Using circuit 0 as an example, register 0 can first receive from the MCU 302 data that configure circuit 0 to perform a first operation. During the time when circuit 0 is performing the first operation, the MCU 302 can send, to register 0′, data that configure circuit 0 to perform a second operation subsequent to the first operation. That is, the bus 304 is not idle when circuit 0 is performing the first operation. After circuit 0 completes the first operation, the MCU can send an enable signal to make a switch between register 0 and register 0′. As such, circuit 0 can perform the second operation as indicated by the data in register 0′. In some implementations, during the time when circuit 0 performs the second operation, the MCU 302 can send, to register 0, data that configure circuit 0 to perform a third operation subsequent to the second operation.

The architecture of one circuit 310 having two registers 312, 314 can increase the operational efficiency of the MCU 302. For example, the MCU 302 does not have to wait until the circuit 310 completes an operation to transfer data configuring a next operation. The MCU 302 can transfer the data configuring a subsequent operation (e.g., to backup register 314) during the time when the circuit 310 is performing the current operation (e.g., as indicated by data in prime register 312).

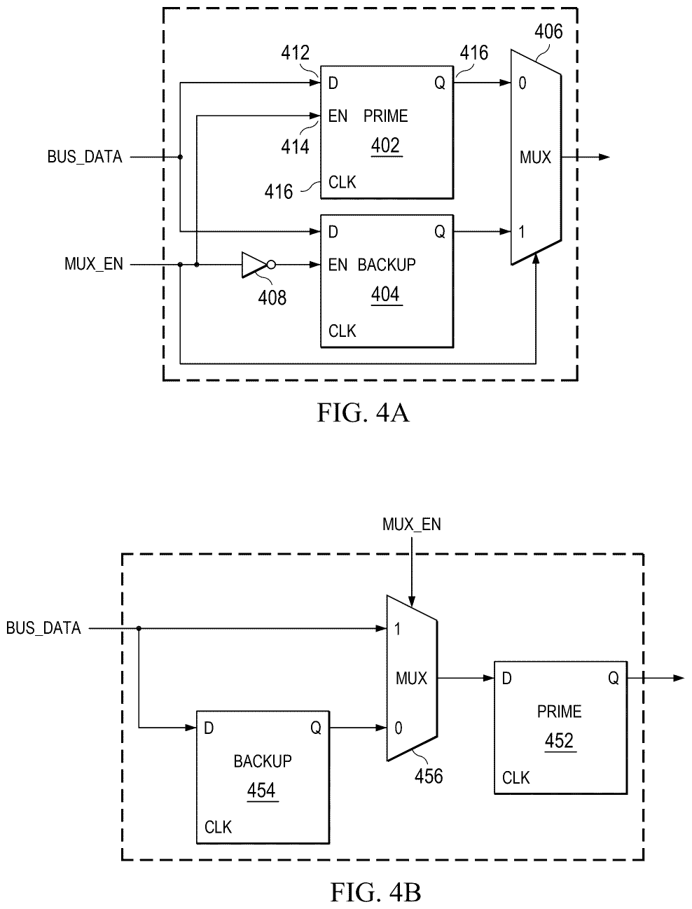

FIG. 4A illustrates an example of a schematic diagram of connection between two registers (e.g., register 0 and register 0′ of FIG. 3) of a circuit (e.g., circuit 0 of FIG. 3), according to some aspects of the present disclosure. Each of prime register 402 and backup register 404 can include an input port 412 that receives data, an enable port 414 that receives enable signals to enable or disable the input port 412 of the register, a clock port 416 that receives clock signals, and an output port 418 that outputs data.

In some implementations, the input ports of the prime register 402 and the backup register 404 can each be connected to a data bus of a MCU (e.g., MCU 302 of FIG. 3). The clock ports of the prime register and the backup register can each be connected to a clock control bus (not shown) of the MCU. The enable ports of the prime register and the backup register can each receive an enable signal (e.g., MUX_EN) from the MCU. In some implementations, an invertor 408 can be added in front of the input port of the backup register 404, to invert the enable signal from high to low (e.g., from 1 to 0), or from low to high (e.g., from 0 to 1). The output port of the backup register can be connected to a first input (e.g., port 1) of the MUX 406. The output port of the prime register can be connected to a second input (e.g., port 0) of the MUX 406. An output of the MUX 406 can be connected to the circuit (e.g., circuit 0 of FIG. 3) to send data from one of the prime register 402 or the backup register 404 to the circuit.

The MUX 406 can also be configured to receive an enable signal (e.g., MUX_EN) from the MCU to select one of the two inputs thereof. For example, when the MCU sets the enable signal to high (e.g., to 1), the input of the prime register 402 is enabled, the input of the backup register 404 is disabled, and the MUX 406 can enable outputting data from the backup register 404 to the circuit. For another example, when the MCU sets the enable signal to low (e.g., to 0), the input of the prime register 402 is disabled, the input of the backup register 404 is enabled, and the MUX can enable outputting data from the prime register 402 to the circuit.

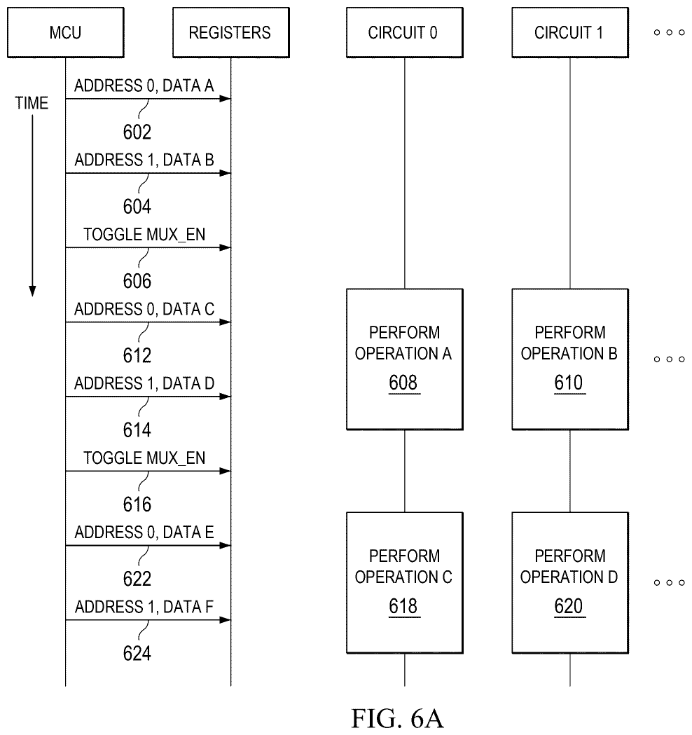

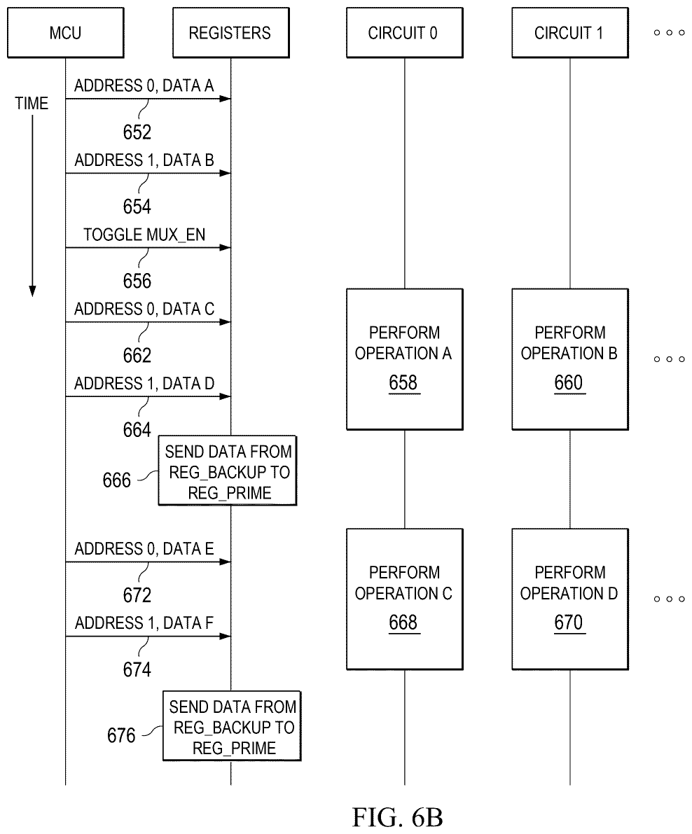

Under the connection scheme of the prime register 402 and the backup register 404 as shown in FIG. 4A, the MCU can control the operations of other circuits of peripheral circuit 102 in a method as shown in FIG. 6A. It should be noted that FIG. 6A shows two circuits for illustration purposes only, and the peripheral circuit 102 can include multiple circuits operating in similar ways.

Before 602, the MCU can set the enable signal to high, so that the input of the prime registers 402 (e.g., register 0, register 1 in FIG. 3) is enabled, and the input of the backup registers 404 (e.g., register 0′, register 1′ in FIG. 3) is disabled.

At 602, the MCU sends data A and address 0 (e.g., address shared by register 0 and register 0′) through a bus (e.g., the bus 304 in FIG. 3). Register 0 receives data A, which can configure circuit 0 to perform operation A.

At 604, the MCU sends data B and address 1 (e.g., address shared by register 1 and register 1′) through the bus. Register 1 receives data B, which can configure circuit 1 to perform operation B.

At 606, after data transmission from the MCU to registers of all target circuits, the MCU can toggle the enable signal from high to low. As such, the input of the prime registers 402 is disabled, the input of the backup registers 404 is enabled, and each MUX 406 can enable outputting from each prime register to its corresponding circuit. In some implementations, 606 can take only one clock.

At 608, circuit 0 performs operation A based on configuration parameters in data A stored in register 0. In the meantime, register 0 can hold data A until operation A is completed.

At 610, circuit 1 performs operation B based on configuration parameters in data B stored in register 1. In the meantime, register 1 can hold data B until operation B is completed. In some implementations, 506 and 508 can start synchronously, according to the clock signal transmitted by a clock control bus.

At 612, during the time when circuit 0 is performing operation A, the MCU sends data C and address 0 through the bus. Register 0′ receives data C, which can configure circuit 0 to perform operation C.

At 614, during the time when circuit 1 is performing operation B, the MCU sends data D and address 1 through the bus. Register l′ receives data D, which can configure circuit 1 to perform operation D.

At 616, after all target circuits (e.g., circuit 0 and peripheral 1) complete their operations (e.g., operation A and operation B), the MCU can toggle the enable signal from low to high. As such, the input of the prime registers 402 is enabled, the input of the backup registers 404 is disabled, and each MUX 406 can enable outputting from each backup register to its corresponding circuit. In some implementations, 616 can take only one clock.

At 618, circuit 0 performs operation C based on configuration parameters in data C stored in register 0′. In the meantime, register 0′ can hold data C until operation C is completed.

At 620, circuit 1 performs operation D based on configuration parameters in data D stored in register 1′. In the meantime, register 1′ can hold data D until operation D is completed. In some implementations, 618 and 620 can start synchronously.

At 622, during the time when circuit 0 is performing operation C, the MCU sends data E and address 0 through the bus. Register 0 receives data E, which can configure circuit 0 to perform operation E.

At 624, during the time when circuit 1 is performing operation D, the MCU sends data F and address 1 through the bus. Register 1 receives data F, which can configure circuit 1 to perform operation F.

Subsequent operations can be conducted in a sequence as described above, without further elaboration.

FIG. 4B illustrates another example of a schematic diagram of connection between two registers (e.g., register 0 and register 0′ of FIG. 3) of a circuit (e.g., circuit 0 of FIG. 3), according to some aspects of the present disclosure.

In some implementations, an input port of a backup register 454 and a first input (e.g., port 1) of a MUX 456 can each be connected to a data bus of an MCU. An output port of the backup register can be connected to a second output (e.g., port 0) of the MUX 456. An output of the MUX 456 can be connected to an input port of a prime register 452. An output port of the prime register 452 can be connected to the circuit (e.g., circuit 0 of FIG. 3) to send data to the circuit.

The MUX 456 can also be configured to receive an enable signal (e.g., MUX_EN) from the MCU to select one of the two inputs thereof. For example, when the MCU sets the enable signal to high (e.g., to 1), the MUX 406 can enable outputting data from the data bus to the prime register 452. For another example, when the MCU sets the enable signal to low (e.g., to 0), the MUX can enable outputting data from the backup register 454 to the prime register 452.

Under the connection scheme of the prime register 452 and the backup register 454 as shown in FIG. 4B, the MCU can control the operations of other circuits of the peripheral circuit 102 in a method as shown in FIG. 6B. It should be noted that FIG. 6B shows two circuits for illustration purposes only, and the peripheral circuit 102 can include multiple circuits operating in similar ways.

Before 652, the MCU can set the enable signal to high, so that the MUX 456 can enable outputting from the data bus to the prime registers 452 (e.g., register 0 and register 1 in FIG. 3).

At 652, the MCU sends data A and address 0 (e.g., address shared by register 0 and register 0′) through a bus (e.g., the bus 304 in FIG. 3). Register 0 receives data A, which can configure circuit 0 to perform operation A.

At 654, the MCU sends data B and address 1 (e.g., address shared by register 1 and register 1′) through the bus. Register 1 receives data B, which can configure circuit 1 to perform operation B.

At 656, after data transmission from the MCU to registers of all target circuits, the MCU can toggle the enable signal from high to low. As such, the MUX enables outputting from the backup registers (e.g., register 0′ and register 1′) to prime registers (e.g., register 0 and register 1). In some implementations, 656 can take only one clock.

At 658, circuit 0 performs operation A based on configuration parameters in data A stored in register 0. In the meantime, register 0 can hold data A until operation A is completed.

At 660, circuit 1 performs operation B based on configuration parameters in data B stored in register 1. In the meantime, register 1 can hold data B until operation B is completed. In some implementations, 506 and 508 can start synchronously.

At 662, during the time when circuit 0 is performing operation A, the MCU sends data C and address 0 through the bus. Register 0′ receives data C, which can configure circuit 0 to perform operation C.

At 664, during the time when circuit 1 is performing operation B, the MCU sends data D and address 1 through the bus. Register 1′ receives data D, which can configure circuit 1 to perform operation D.

At 666, after all target circuits (e.g., circuit 0 and peripheral 1) complete their operations (e.g., operation A and operation B), register 0′ sends data C to register 0, and in parallel, register l′ sends data D to register 1.

At 668, circuit 0 performs operation C based on configuration parameters in data C stored in register 0. In the meantime, register 0 can hold data C until operation C is completed.

At 670, circuit 1 performs operation D based on configuration parameters in data B stored in register 1. In the meantime, register 1 can hold data D until operation D is completed. In some implementations, 668 and 670 can start synchronously.

At 672, during the time when circuit 0 is performing operation C, the MCU sends data E and address 0 through the bus. Register 0′ receives data E, which can configure circuit 0 to perform operation E.

At 674, during the time when circuit 1 is performing operation D, the MCU sends data F and address 1 through the bus. Register 1′ receives data F, which can configure circuit 1 to perform operation F.

At 676, after all target circuits (e.g., circuit 0 and peripheral 1) complete their operations (e.g., operation C and operation D), register 0′ sends data E to register 0, and in parallel, register 1′ sends data F to register 1.

Subsequent operations can be conducted in a sequence as described above, without further elaboration.

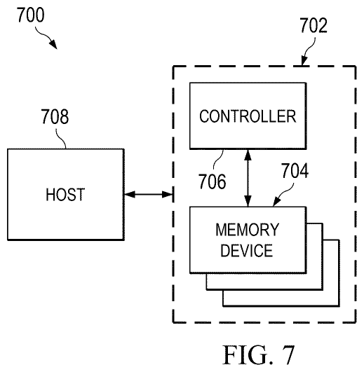

FIG. 7 illustrates a block diagram of an example system 700 having a memory device, according to some aspects of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, system 700 can include a host 708 and a memory system 702 having one or more memory devices 704 and a memory controller 706. Host 708 can be a processor of an electronic device, such as a central processing unit (CPU), or a system-on-chip (SoC), such as an application processor (AP). Host 708 can be configured to send or receive data to or from memory devices 704.

Memory device 704 can be any memory device disclosed in the present disclosure. Memory controller 706 is coupled to memory device 704 and host 708 and is configured to control memory device 704, according to some implementations. Memory controller 706 can manage the data stored in memory device 704 and communicate with host 708. In some implementations, memory controller 706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed for operating in a high duty-cycle environment SSDs or embedded multi-media-cards (eMMCs) used as data storage for mobile devices, such as smartphones, tablets, laptop computers, etc., and enterprise storage arrays. Memory controller 706 can be configured to control operations of memory device 704, such as read, erase, and program operations. Memory controller 706 can also be configured to manage various functions with respect to the data stored or to be stored in memory device 704 including, but not limited to bad-block management, garbage collection, logical-to-physical address conversion, wear leveling, etc. In some implementations, memory controller 706 is further configured to process error correction codes (ECCs) with respect to the data read from or written to memory device 704. Any other suitable functions may be performed by memory controller 706 as well, for example, formatting memory device 704.

Memory controller 706 can communicate with an external device (e.g., host 708) according to a particular communication protocol. For example, memory controller 706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

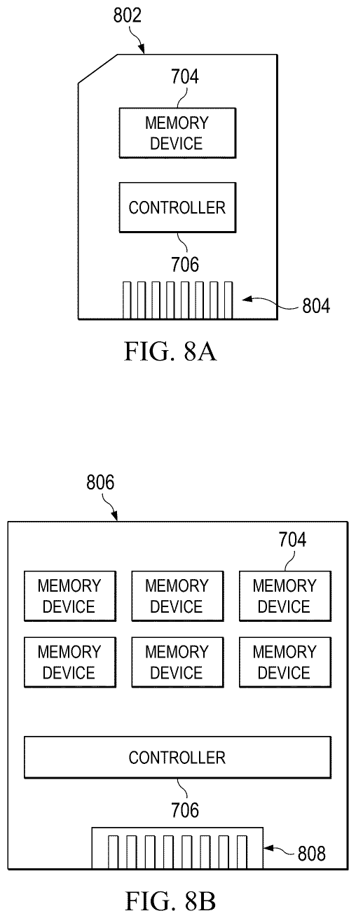

Memory controller 706 and one or more memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 8A, memory controller 706 and a memory device 704 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 802 can further include a memory card connector 804 coupling memory card 802 with a host. In another example as shown in FIG. 8B, memory controller 706 and multiple memory devices 704 may be integrated into an SSD 806. SSD 806 can further include an SSD connector 808 coupling SSD 806 with a host. In some implementations, the storage capacity and/or the operation speed of SSD 806 is greater than those of memory card 802.

According to one aspect of the present disclosure, a method for operating a memory device is provided. The memory device includes a memory array that includes memory cells and a peripheral circuit coupled to the memory array. The peripheral circuit includes a micro controller unit (MCU) and a plurality of circuits controlled by the MCU. The MCU is configured to switch between a first register and a second register that are coupled to a first circuit of the plurality of circuits.

The method can include one or more of the following features.

In some implementations, an address of the first register is same as an address of the second register.

In some implementations, the peripheral circuit is configured to perform the following operations. During a first time period, send first data corresponding to a first operation from the MCU to the first register. During a second time period, perform the first operation by the first circuit, and send second data corresponding to a second operation from the MCU to the second register. The second operation is subsequent to the first operation.

In some implementations, a multiplexer (MUX) is coupled between the first register and the second register. The MCU is configured to send an enable signal to the MUX to enable the switch between the first register and the second register.

In some implementations, the MCU is configured to send the enable signal to the MUX after the first time period and before the second time period.

In some implementations, the MCU is configured to switch between a third register and a fourth register that are coupled to a second circuit of the plurality of circuits. The peripheral circuit is configured to perform the following operations. During the first time period, send third data corresponding to a third operation from the MCU to the third register. During the second time period, perform the third operation by the second circuit, and send fourth data corresponding to a fourth operation from the MCU to the fourth register. The fourth operation is subsequent to the third operation.

In some implementations, the peripheral circuit is configured to perform the following operations. During a third time period, perform the second operation by the first circuit, and send fifth data corresponding to a fifth operation from the MCU to the first register. The fifth operation is subsequent to the second operation.

In some implementations, the MUX is coupled to an output terminal of the first register and an output terminal of the second register.

In some implementations, the enable signal is sent to the MUX, an enable terminal of the first register, and an enable terminal of the second register. The enable signal indicates to turn off an input terminal of the first register and the output terminal of the second register, and turn on the output terminal of the first register and an input terminal of the second register.

In some implementations, the peripheral circuit is configured to perform the following operations. During a third time period, send the second data from the second register to the first register, perform the second operation by the first circuit, and send sixth data corresponding to a sixth operation from the MCU to the second register. The sixth operation is subsequent to the second operation.

In some implementations, the MUX is coupled to an output terminal of the second register and a data bus of the MCU.

In some implementations, the enable signal is sent to the MUX and indicates to send data from the second register to the first register.

According to another aspect of the present disclosure, a method for operating a memory device is provided. The method includes, during a first time period, sending first data corresponding to a first operation from a micro controller unit (MCU) to a first register. The memory device includes a peripheral circuit that includes the MCU and a plurality of circuits controlled by the MCU. The first register is coupled to a first circuit of the plurality of circuits. The method further includes, during a second time period, performing the first operation by the first circuit, and sending second data corresponding to a second operation from the MCU to a second register coupled to the first circuit. The second operation is subsequent to the first operation.

The method can include one or more of the following features.

In some implementations, an address of the first register is same as an address of the second register.

In some implementations, the method further includes, sending, by the MCU after the first time period and before the second time period, a first enable signal that indicates to switch between the first register and the second register.

In some implementations, the method further includes, during the first time period, sending third data corresponding to a third operation from the MCU to a third register. The third register is coupled to a second circuit of the plurality of circuits. The method further includes, during the second time period, performing the third operation by the second circuit, and sending fourth data corresponding to a fourth operation from the MCU to a fourth register coupled to the second circuit. The fourth operation is subsequent to the third operation.

In some implementations, the method further includes, during a third time period, performing the second operation by the first circuit, and sending fifth data corresponding to a fifth operation from the MCU to the first register. The fifth operation is subsequent to the second operation.

In some implementations, the method further includes, sending, by the MCU after the second time period and before the third time period, a second enable signal that indicates to switch between the first register and the second register.

In some implementations, the method further includes, during a third time period, sending the second data from the second register to the first register, performing the second operation by the first circuit, and sending sixth data corresponding to a sixth operation from the MCU to the second register. The sixth operation is subsequent to the second operation.

According to another aspect of the present disclosure, a memory system is provided. The memory system includes a memory device and a memory controller coupled to the memory device. The memory device includes a memory array that includes memory cells and a peripheral circuit coupled to the memory array. The peripheral circuit includes a micro controller unit (MCU) and a plurality of circuits controlled by the MCU. The MCU is configured to switch between a first register and a second register that are coupled to a first circuit of the plurality of circuits. The peripheral circuit is configured to perform the following operations. During a first time period, send first data corresponding to a first operation from the MCU to the first register. During a second time period, perform the first operation by the first circuit, and send second data corresponding to a second operation from the MCU to the second register. The second operation is subsequent to the first operation. The controller is configured to send signals to the memory device to initiate the first operations and the second operation.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

It is noted that references in the specification to “one implementation,” “an implementation,” “an example implementation,” “some implementation,” etc., indicate that the implementation described can include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure, or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures, or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and can, instead, allow for existence of additional factors not necessarily expressly described, again, depending at least in part on context.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A memory device, comprising:
a memory array comprising memory cells; and
a peripheral circuit coupled to the memory array, wherein the peripheral circuit comprises a micro controller unit (MCU) and a plurality of circuits controlled by the MCU, wherein the MCU is configured to switch between a first register and a second register that are coupled to a first circuit of the plurality of circuits.

2. The memory device of claim 1, wherein an address of the first register is same as an address of the second register.

3. The memory device of claim 1, wherein the peripheral circuit is configured to:
during a first time period, send first data corresponding to a first operation from the MCU to the first register; and
during a second time period:
perform the first operation by the first circuit; and
send second data corresponding to a second operation from the MCU to the second register, wherein the second operation is subsequent to the first operation.

4. The memory device of claim 3, wherein a multiplexer (MUX) is coupled between the first register and the second register, and wherein the MCU is configured to send an enable signal to the MUX to enable the switch between the first register and the second register.

5. The memory device of claim 4, wherein the MCU is configured to send the enable signal to the MUX after the first time period and before the second time period.

6. The memory device of claim 3, wherein the MCU is configured to switch between a third register and a fourth register that are coupled to a second circuit of the plurality of circuits, wherein the peripheral circuit is configured to:
during the first time period, send third data corresponding to a third operation from the MCU to the third register; and
during the second time period:
perform the third operation by the second circuit; and
send fourth data corresponding to a fourth operation from the MCU to the fourth register, wherein the fourth operation is subsequent to the third operation.

7. The memory device of claim 3, wherein the peripheral circuit is configured to:
during a third time period:
perform the second operation by the first circuit; and
send fifth data corresponding to a fifth operation from the MCU to the first register, wherein the fifth operation is subsequent to the second operation.

8. The memory device of claim 4, wherein the MUX is coupled to an output terminal of the first register and an output terminal of the second register.

9. The memory device of claim 8, wherein the enable signal is sent to the MUX, an enable terminal of the first register, and an enable terminal of the second register, and wherein the enable signal indicates to:
turn off an input terminal of the first register and the output terminal of the second register; and
turn on the output terminal of the first register and an input terminal of the second register.

10. The memory device of claim 3, wherein the peripheral circuit is further configured to:
during a third time period:
send the second data from the second register to the first register;
perform the second operation by the first circuit; and
send sixth data corresponding to a sixth operation from the MCU to the second register, wherein the sixth operation is subsequent to the second operation.

11. The memory device of claim 4, wherein the MUX is coupled to an output terminal of the second register and a data bus of the MCU.

12. The memory device of claim 11, wherein the enable signal is sent to the MUX and indicates to send data from the second register to the first register.

13. A method for operating a memory device, wherein the method comprises:
during a first time period, sending first data corresponding to a first operation from a micro controller unit (MCU) to a first register, wherein the memory device comprises a peripheral circuit comprising the MCU and a plurality of circuits controlled by the MCU, and wherein the first register is coupled to a first circuit of the plurality of circuits; and
during a second time period:
performing the first operation by the first circuit; and
sending second data corresponding to a second operation from the MCU to a second register coupled to the first circuit, wherein the second operation is subsequent to the first operation.

14. The method of claim 13, wherein an address of the first register is same as an address of the second register.

15. The method of claim 13, further comprising:
sending, by the MCU after the first time period and before the second time period, a first enable signal that indicates to switch between the first register and the second register.

16. The method of claim 13, further comprising:
during the first time period, sending third data corresponding to a third operation from the MCU to a third register, wherein the third register is coupled to a second circuit of the plurality of circuits; and
during the second time period:
performing the third operation by the second circuit; and
sending fourth data corresponding to a fourth operation from the MCU to a fourth register coupled to the second circuit, wherein the fourth operation is subsequent to the third operation.

17. The method of claim 13, further comprising:
during a third time period:
performing the second operation by the first circuit; and
sending fifth data corresponding to a fifth operation from the MCU to the first register, wherein the fifth operation is subsequent to the second operation.

18. The method of claim 17, further comprising:
sending, by the MCU after the second time period and before the third time period, a second enable signal that indicates to switch between the first register and the second register.

19. The method of claim 13, further comprising:
during a third time period:
sending the second data from the second register to the first register;
performing the second operation by the first circuit; and
sending sixth data corresponding to a sixth operation from the MCU to the second register, wherein the sixth operation is subsequent to the second operation.

20. A memory system, comprising:
a memory device, comprising:
a memory array comprising memory cells; and
a peripheral circuit coupled to the memory array, wherein the peripheral circuit comprises a micro controller unit (MCU) and a plurality of circuits controlled by the MCU, wherein the MCU is configured to switch between a first register and a second register that are coupled to a first circuit of the plurality of circuits, and wherein the peripheral circuit is configured to:
during a first time period, send first data corresponding to a first operation from the MCU to the first register; and
during a second time period:
perform the first operation by the first circuit; and
send second data corresponding to a second operation from the MCU to the second register, wherein the second operation is subsequent to the first operation; and
a controller coupled to the memory device and configured to send signals to the memory device to initiate the first operation and the second operation.
